(19) United States
(12) Patent Application Publication
(10) Pub. No.: US 2008/0110494 A1
(43) Pub. Date: May 15, 2008

(54) NANOPARTICLE SENSITIZED NANOSTRUCTURED SOLAR CELLS

(75) Inventor: Damoder Reddy, Los Gatos, CA (US)

Correspondence Address: MORGAN, LEWIS & BOCKIUS, LLP, ONE MARKET SPEAR STREET TOWER, SAN FRANCISCO, CA, 94105, US

(73) Assignee: SOLEXANT CORP., Los Gatos, CA (US)

(21) Appl. No.: 11/675,586

(22) Filed: Feb. 15, 2007

Related U.S. Application Data
(60) Provisional application No. 60/773,838, filed on Feb. 16, 2006.
(60) Provisional application No. 60/786,134, filed on Mar. 27, 2006.
(60) Provisional application No. 60/786,526, filed on Mar. 28, 2006.

(51) Int. Cl. H01L 31/00; B05D 5/12

(52) U.S. Cl. 136/255; 136/256; 427/74

(57) ABSTRACT

In general, the invention relates to the field of photovoltaics or solar cells. More particularly the invention relates to photovoltaic devices using metal oxide nanostructures in connection with photoactive nanoparticles including nanoparticles of different size and composition to form a photovoltaic device.

### FIELD OF THE INVENTION

In general, the invention relates to the field of photovoltaics or solar cells. More particularly the invention relates to photovoltaic devices using nanostructures in connection with photoactive nanoparticles including nanoparticles of different size and composition to form photovoltaic devices.

### BACKGROUND OF THE INVENTION

Increasing oil prices have heightened the importance of developing cost effective renewable energy. Significant efforts are underway around the world to develop cost effective solar cells to harvest solar energy. Current solar energy technologies can be broadly categorized as crystalline silicon and thin film technologies. More than 90% of the solar cells are made from silicon single crystal silicon, polycrystalline silicon or amorphous silicon.

Historically, crystalline silicon (c-Si) has been used as the light-absorbing semiconductor in most solar cells, even though it is a relatively poor absorber of light and requires a considerable thickness (several hundred microns) of material. Nevertheless, it has proved convenient because it yields stable solar cells with good efficiencies (12-20%, half to two-thirds of the theoretical maximum) and uses process technology developed from the knowledge base of the microelectronics industry.

Two types of crystalline silicon are used in the industry. The first is monocrystalline, produced by slicing wafers (approximately 150 mm diameter and 350 microns thick) from a high-purity single crystal boule. The second is multicrystalline silicon, made by sawing a cast block of silicon first into bars and then wafers. The main trend in crystalline silicon cell manufacture is toward multicrystalline technology. For both mono- and multicrystalline Si, a semiconductor p-n junction is formed by diffusing phosphorus (an n-type dopant) into the top surface of the boron doped (p-type) Si wafer. Screen-printed contacts are applied to the front and rear of the cell, with the front contact pattern specially designed to allow maximum light exposure of the Si material with minimum electrical (resistive) losses in the cell.

Silicon solar cells are very expensive. Manufacturing is mature and not amenable for significant cost reduction. Silicon is not an ideal material for use in solar cells as it primarily absorbs in the visible region of the solar spectrum thereby limiting the conversion efficiency.

Second generation solar cell technology is based on thin films. Two main thin film technologies are Amorphous Silicon and CIGS.

Amorphous silicon (a-Si) was viewed as the “only” thin film PV material in the 1980s. But by the end of that decade, and in the early 1990s, it was dismissed by many observers for its low efficiencies and instability. However, amorphous silicon technology has made good progress toward developing a very sophisticated solution to these problems: multijunction configurations. Now, commercial, multijunction a-Si modules could be in the 7%-9% efficiency range. United Solar Systems Corporation and Kanarka plan have built 25-MW manufacturing facilities and several companies have announced plans to build manufacturing plants in Japan and Germany. BP Solar and United Solar Systems Corporation plan to build 10 MW facilities in the near future.

The key obstacles to a-Si technology are low efficiencies (about 11% stable), light-induced efficiency degradation (which requires more complicated cell designs such as multiple junctions), and process costs (fabrication methods are vacuum-based and fairly slow). All of these issues are important to the potential of manufacturing cost-effective a-Si modules.

Thin film solar cells made from Copper Indium Gallium Diselenide (CIGS) absorbers show promise in achieving high conversion efficiencies of 10-12%. The record high efficiency of CIGS solar cells (19%-% NREL) is by far the highest compared with those achieved by other thin film technologies such as Cadmium Telluride (CdTe) or amorphous Silicon (a-Si).

These record breaking small area devices have been fabricated using vacuum evaporation techniques which are capital intensive and quite costly. It is very challenging to fabricate CIGS films of uniform composition on large area substrates. This limitation also affects the process yield, which are generally quite low. Because of these limitations, implementation of evaporation techniques has not been successful for large-scale, low-cost commercial production of thin film solar cells and modules and is non-competitive with today's crystalline silicon solar modules.

To overcome the limitations of the physical vapor deposition techniques that use expensive vacuum equipment, several companies have been developing high throughput vacuum processes (ex. DayStar, Global Solar) and non-vacuum processes (ex: ISET, Nanosolar) for the fabrication of CIGS solar cells. Using ink technology, very high active materials utilization can be achieved with relatively low capital equipment costs. The combined effect is a low-cost manufacturing process for thin film solar devices. CIGS can be made on flexible substrates making it possible to reduce the weight of solar cells. Cost of CIGS solar cells is expected to be lower than crystalline silicon making them competitive even at lower efficiencies. Two main problems with CIGS solar cells are: (1) there is no clear pathway to higher efficiency and (2) high processing temperatures make it difficult to use high speed roll to roll process and hence they will not be able to achieve significantly lower cost structure.

These are significant problems with the currently available technologies. Crystalline silicon solar cells which have >90% market share today are very expensive. Solar energy with c-silicon solar cells costs about 25 cents per kwh as compared to less than 10 cents per kwh for fossil fuels. In addition, the capital cost of installing solar panels is extremely high limiting its adoption rate. Crystalline solar cell technology is mature and unlikely to improve performance or cost competitiveness in near future. Amorphous silicon thin film technology is amenable to high volume manufacturing that could lead to low cost solar cells. In addition, amorphous and microcrystal silicon solar cells absorb only in the visible region.

Next generation solar cells are required to truly achieve high efficiencies with light weight and low cost. Two potential candidates are (1) polymer solar cells and (2) nanoparticle solar cells. Polymer solar cells have the potential to be low cost due to roll to roll processing at moderate temperatures (<150 C). However, polymers suffer from two main drawbacks: (1) poor efficiencies due slow charge transport and (2) poor stability-especially to UV. Hence it is unlikely that polymer solar cells will be able to achieve the required performance to become the next generation solar cell. The most promising technology for the next generation solar cell is based on quantum dot nanoparticles.

Several research groups have been conducting experimental studies on quantum dot based solar cells. Most commonly used quantum dots are made of compound semiconductors such as Group II-VI, II-IV and III-V. Some examples of these photosensitive quantum dots are CdSe, CdTe, PbSe, PbS, ZnSe.

Solar cells made from photosensitive nanoparticles as described in the art show very low efficiencies (<5%). Nanoparticles are very efficient in generating electron hole charge pairs when exposed to sunlight. The primary reason for these low efficiencies is charge recombination. To achieve high efficiencies in a solar cell the charges must be separated as soon as they are generated. Charges that recombine do not produce any photocurrent and hence do not contribute towards solar cell efficiency. Charge recombination in nanoparticles is primarily due to two factors: (1) surface states on nanoparticle that facilitate charge recombination, and (2) slow charge transport. In the later case, charge recombination is generally faster compared to the charge transport rate because charges travel slowly through the electron transport and hole transport layers.

Various methods have been reported in the prior art to solve these problems of nanoparticles. Surface treatment techniques have been tried to remove surface states. (See Furis et al, MRS Proceedings, volume 784, 2004) Such techniques show improvement in photoluminescence but do not improve solar conversion efficiency as then do not impact the charge transport properties of hole transport and electron transport layers.

It is known in the art that TiO₂ layers can be used to rapidly transport electrons. Dye-sensitized solar cells use TiO₂ precisely for this reason. Transparent TiO₂ nanotubes have been reported in the literature (Mor et al., Adv. Funct. Mater., 2005, 15, 1291-1296 (2005)). These TiO₂ nanotubes have been used to prepare dye-sensitized solar cells.

### SUMMARY OF THE INVENTION

The photovoltaic devise includes first and second electrodes at least one of which is transparent to solar radiation. A first layer comprising an electron conducting nanostructure is in electrical communication with the first electrode. A photoactive layer comprising photosensitive nanoparticles is placed in proximity to the electron conducting nanostructure. A hole conducting layer is in contact with the photoactive layer and the second electrode. A blocking layer between the hole conducting layer and the first electrode can also be included.

The electron conducting nanostructure can be nanotubes, nanorods, or nanowires. A preferred nanotube is made from TiO₂. A preferred nanowire is made from ZnO.

The photosensitive nanoparticles can be quantum dots, nanorods, nanobipods, nanotripods, nanomultipods or nanowires. In some cases, the photosensitive nanoparticle is covalently attached to the nanostructure. Preferred photosensitive nanoparticles include CdSe, ZnSe, PbSe, InP, PbS, ZnS, Si, Ge, SiGe, CdTe, CdHgTe, or Group II-VI, II-IV or III-V materials. In some embodiments first and second nanoparticle that adsorb radiation from different portions of the solar spectrum are used in the photovoltaic device. The first and second nanoparticles can differ in composition, size or a combination of size and composition.

In another embodiment, a second photoactive layer is used that contains nanoparticles that adsorb radiation from a different portion of the solar spectrum as compared to the nanoparticles of the first layer. The nanoparticles in the first and said second photoactive layer can differ in composition, size or a combination of size and composition.

In some embodiments, the hole conducting layer is a hole conducting polymer such as a p-type semiconducting polymer. Examples of p-type semiconducting polymers include P3HT, P3OT, MEH-PPV or PEDOT. In other embodiments, the hole conducting layer is a p-type semiconductor. Examples of p-type semiconductor include p-doped Si, p-doped Ge or p-doped SiGe. In the case of Si the p-type semiconductor can be p-doped amorphous silicon, p-doped microcrystalline silicon or p-doped nanocrystalline silicon. In some cases the hole conducting layer is made of two or more layers of p-type semiconductor. The p-type semiconductor layers can be a p-doped silicon layer, a p-doped germanium layer and/or a p-doped SiGe layer.

The photovoltaic devise can be made by forming a first layer containing electron conducting nanostructures on a first electrode so that the first layer is in electrical communication with the first electrode. A photoactive layer containing photosensitive nanoparticles is then formed on the electron conducting nanostructure. A hole transport layer is then formed on the photoactive layer. A second electrode is then found on the hole transport layer. At least one of the first and second electrodes is transparent to solar radiation. A blocking layer can also be incorporated before the nanostructure or hole conducting layer is formed. Different nanoparticles can be used to make the photoactive layer to produce a random distribution of the different nanoparticles in the layer. In another embodiment, the photoactive layer is made of at least two layers of different nanoparticles. In this case the method includes forming a layer of first nanoparticles on the nanostructures and forming a layer of second nanoparticles on the layer of the first nanoparticles.

### BRIEF DESCRIPTION OF THE DRAWING

FIG. 1 (Prior Art) depicts nanometer quantum dots of different size that absorb and emit radiation having different colors. Small dots absorb in the blue end of the spectrum while the large size dots absorb in the red end of the spectrum.

FIG. 2 (Prior Art) depicts quantum dots made from ZnSe, CdSe and PbSe that absorb/emit in UV visible and IR respectively.

FIG. 3 (Prior Art) depicts nanoparticles capped with solvents such as tri-n-octyl phosphine oxide (TOPO).

FIG. 4 depicts nanoparticles functionalized with an R group. The R group can be represented as Xₐ—Rₙ—Y_{b} where X and Y are reactive moieties such as a carboxylic acid (—COOH) group, a phosphoric acid (—H₂PO₄) group, a sulfonic acid (—HSO₃) group or an amine, a and b are 0 or 1 where one of a and b are 1, R is carbon, or oxygen and n=0-10 or 0-5.

FIGS. 5A-5F depict the formation of a solar cell according to one embodiment. In FIG. 5A, a titanium thin film is deposited on fluorine doped tin oxide deposited on a transparent substrate. In FIG. 5B, TiO₂ nanotubes on fluorine doped tin oxide are deposited on a transparent substrate. In FIG. 5C, TiO₂ nanotubes with hydroxyl functional groups are deposited on the fluorine doped tin oxide deposited on a transparent substrate. In FIG. 5D, nanoparticle sensitizers are attached to the TiO₂ nanotubes. In FIG. 5E, a transparent hole transport layer such as ITO, PEDOT, etc., is deposited on nanoparticle sensitizer. In FIG. 5F, an electrode layer (ITO or metal) is deposited on nanoparticle sensitized TiO₂ nanotubes on fluorine doped tin oxide deposited on a transparent substrate.

FIG. 6 depicts a nanoparticle sensitized solar cell of FIG. 5F receiving sunlight (100) to produce voltage.

FIG. 7 depicts another embodiment of a nanoparticle sensitized solar cell with a titanium metal foil as substrate and electrode.

FIG. 8 depicts a nanoparticle sensitized solar cell with TiO₂ nanorods on fluorine doped tin oxide.

FIG. 9 depicts an alternate embodiment of a nanoparticle sensitized solar cell with TiO₂ nanorods on titanium metal foil.

FIG. 10 depicts a broadband embodiment of the solar cell of FIG. 6 where quantum dots of different size and/or composition are randomly distributed on the TiO₂ nanotubes.

FIG. 11 depicts a broadband embodiment of the solar cell of FIG. 7 where quantum dots of different size and/or composition are randomly distributed on the TiO₂ nanotubes.

FIG. 12 depicts a broadband embodiment of the solar cell of FIG. 9 where quantum dots of different size and/or composition are randomly distributed on the TiO₂ nanotubes.

FIG. 13 depicts a broadband embodiment of the solar cell of FIG. 8 where quantum dots of different size and/or composition are randomly distributed on the TiO₂ nanotubes.

FIG. 14 depicts a broadband embodiment of the solar cell of FIG. 6 where layers of quantum dots of different size and/or composition are positioned on the TiO₂ nanotubes.

FIG. 15 depicts a broadband embodiment of the solar cell of FIG. 7 where layers of quantum dots of different size and/or composition are positioned on the TiO₂ nanotubes.

FIG. 16 depicts a broadband embodiment of the solar cell of FIG. 8 where layers of quantum dots of different size and/or composition are positioned on the TiO₂ nanotubes.

FIG. 17 depicts a broadband embodiment of the solar cell of FIG. 9 where layers of quantum dots of different size and/or composition are positioned on the TiO₂ nanotubes.

### DETAILED DESCRIPTION OF THE INVENTION

An embodiment of the photovoltaic device disclosed herein is made from two electrodes, a first layer comprising electron conducting nanostructures, a photoactive layer comprising photosensitive nanoparticles in proximity to the electronic conducting nanostructures, and a hole transport layer in contact with the photoactive layer. The first layer is in electrical communication with the first electrode. The hole transport layer is in contact with the photoactive layer and the second electrode. At least one of the first and second electrodes is transparent to solar radiation.

As used herein, the term 4“nanostructure” or “electron conducting nanostructure” refers to nanotubes, nanorods, nanowires, etc. Electron conducting nanostructures are crystalline in nature. In general, the nanostructures are made from wide band gap semiconductor materials where the band gap is, for example, 3.2 eV for TiO₂. The nanostructures are chosen so that their band gap is higher than the highest band gap of the photoactive nanoparticle to be used in the solar cell (e.g., >2.0 eV).

Electron conducting nanostructures can be made, for example, from titanium dioxide, zinc oxide, tin oxide, indium tin oxide (ITO) and indium zinc oxide. The nanostructures may also be made from other conducting materials, such as carbon nanotubes. The nanostructures can be grown directly on a metal foil, glass substrate, or a plastic substrate coated with a thin conducting metal or metal oxide film, such as fluorine-doped tin oxide. For TiO₂ nanostructures, see, e.g. Mor et al., “Use of Highly-Ordered TiO₂ Nanotube Arrays in Dye-Sensitized Solar Cells.”. Nanoletters Vol. 6, No. 2, pp. 215-218 (2005). Mor et al., Nanoletters Vol. 5, no. 1, pp. 191-195 (2005); Barghese et al., Journal of Nanoscience and Nontechnology, no. 1, Vol. 5, pp. 1158-1165 (2005); and Paulose et al., Nanotechnology 17 pp 1-3 (2006). For ZnO nanowires see Baxter and Aydel, Solar Energy Materials and Solar Cells 90, 607-622 (2006) Greene, et al., Angew. Chem. Int. Ed. 42, 3031-303) (2003); and Law, et al., Nature Materials 4, 455-459 (2005).

Electron conducting nanostructures can be prepared by methods known in the art. For example TiO₂ nanotubes can be made by anodizing a titanium metal film or a titanium metal film deposited on fluorine doped tin oxide. Conducting nanostructures can also be prepared by using colloidal growth facilitated by a seed particle deposited on the substrate. Conducting nanostructures can also be prepared via vacuum deposition process such as chemical vapor deposition (CVD), metal-organic chemical vapor deposition (MOCVD), Epitaxial growth methods such as molecular beam epitaxy (MEB), etc.

In the case of nanotubes, the outside diameter of the nanotube ranges from about 20 nanometers to 100 nanometers, in some cases from 20 nanometers to 50 nanometers, and in others from 50 nanometers to 100 nanometers. The inside diameter of the nanotube can be from about 10 to 80 nanometers, in some cases from 20 to 80 nanometers, and in others from 60 to 80 nanometers. The wall thickness of the nanotube can be 10-25 nanometers, 15-25 nanometers, or 20-25 nanometers. The length of the nanotube in some cases is 100-800 nanometers, 400-800 nanometers, or 200-400 nanometers.

In the case of nanowires, the diameters can be from about 100 nanometers to about 200 nanometers and can be as long as 50-100 microns. Nanorods can have diameters from about 2-200 nanometers hut often are from 5-100 or 20-50 nanometers in diameter. Their length can be 20-100 nanometers, but often are between 50-500 or 20-50 nanometers in length.

As used herein, the term “nanoparticle” or “photosensitive nanoparticle” refers to photosensitive materials that generate electron hole pairs when exposed to solar radiation. Photosensitive nanoparticles are generally nanocrystals such as quantum dots, nanorods, nanobipods, nanotripods, nanomultipods, or nanowires.

Photosensitive nanoparticles can be made from compound semiconductors which include Group II-VI, II-IV and III-V materials. Some examples of photosensitive nanoparticles are CdSe, ZnSe, PbSe, InP, PbS, ZnS, CdTe Si, Ge, SiGe, CdTe, CdHgTe, and Group II-VI, II-IV and III-V materials. Photosensitive nanoparticles can be core type or core-shell type. In a core shell nanoparticle, the core and shell are made from different materials. Both core and shell can be made from compound semiconductors.

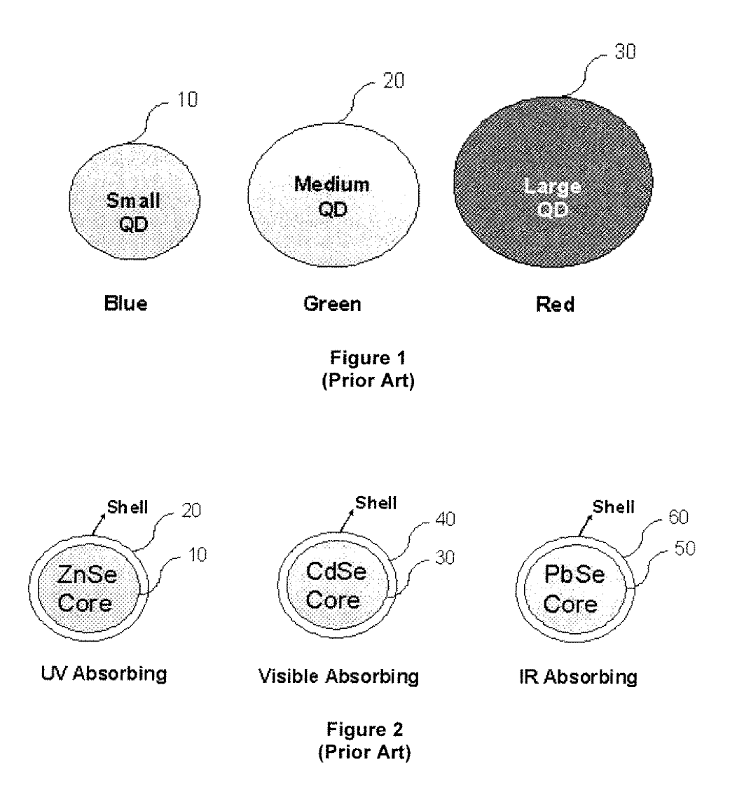

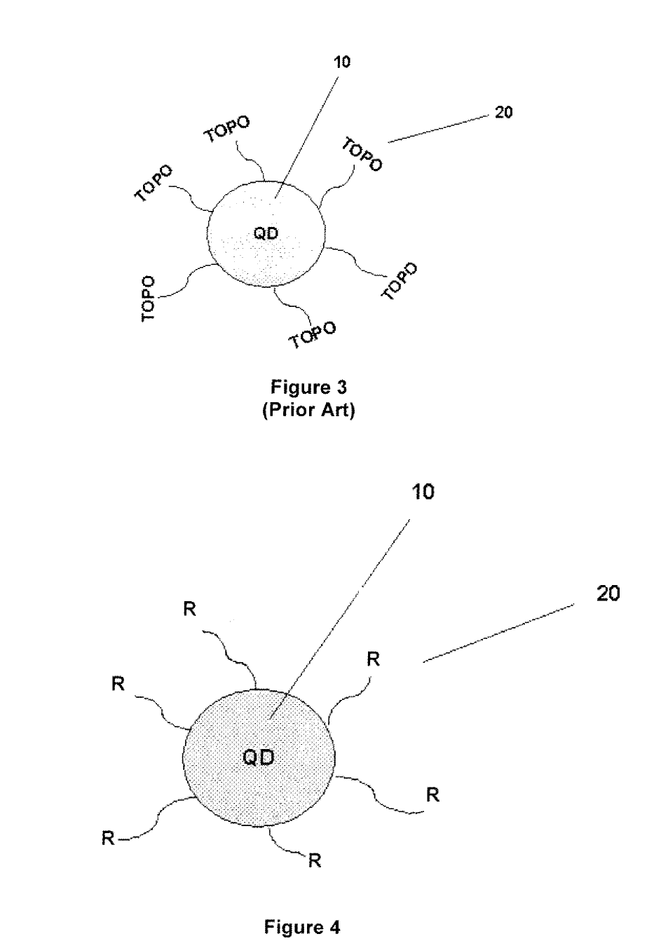

Quantum dots are a preferred nanoparticle. As in known in the art, quantum dots having the same composition but having different diameters absorb and emit radiation at different wave lengths. FIG. 1 depicts three quantum dots made of the same composition but having different diameters. The small quantum dot absorbs and emits in the blue portion of the spectrum; whereas, the medium and large quantum dots absorb and emit in the green and red portions of the visible spectrum, respectively. Alternatively, as shown in FIG. 2, the quantum dots can be essentially the same size but made from different materials. For example, a UV-absorbing quantum dot can be made from zinc selenide whereas, visible and IR quantum, dots can be made from cadmium selenide and lead selenide, respectively. Nanoparticles having different size and/or composition can be used either randomly or in layers to produce a broadband solar cell that absorbs in (1) the UV and visible, (2) the visible and IR, or (3) the UV, visible, and IR.

The photoactive nanoparticle can be modified to contain a linker Xₐ—Rₐ—Y_{b} where X and Y can be reactive moieties such as carboxylic acid groups, phosphonic acid groups, sulfonic acid groups, amine containing groups etc. a and b are independently 0 or 1 where at least one of a and b is 1, R is a carbon, nitrogen or oxygen containing group such as —CH₂, —NH— or —O—, and n is 0-10 or 0-5. One reactive moiety can react with the nanoparticle while the other can react with the nanostructure. For example, when two layers of nanoparticles are disposed on a nanostructure, the nanoparticles of the base layer can contain a linker with an acid functionality which can form a bond with a metal oxide nanostructure. The nanoparticles of the second layer can contain a basic unit such as an amine or hydroyl group to form an amide or ester bond with the acid group of the first nanoparticle linker. The linkers also passivate the nanoparticles and increase their stability, light absorption and photoluminescence. They can also improve the nanoparticle solubility or suspension in common organic solvents.

Functionalized nanoparticles are reacted with suitable reactive groups such as hydroxyl or others on the nanostructures to deposit a monolayer of dense continuous nanoparticles by a molecular self assembly process. By adjusting the components of Xₐ—Rₙ—Y_{b}, the distance between the surface of (1) the nanostructure and nanoparticle or (2) a nanoparticle and another nanoparticle can be adjusted to minimize the effect of surface states in facilitating charge recombination. The distance between these surfaces is typically 10 Angstroms or less preferably 5 angstroms or less. T-his distance is maintained so that electrons tunnel through this Yap from the nanoparticles to the highly conducting nanostructures. This facile electron transport helps in reducing charge recombination and results in efficient charge separation which leads to efficient solar energy conversion.

As used herein a “hole transport layer” is an electrolyte that preferentially conducts holes. Hole transporting layers can be (1) inorganic molecules including p-doped semiconducting materials such as p-type amorphous or microcrystalline silicon or germanium, (2) organic molecules such as metal-thalocyanines, aryl amines etc. and (3) conducting polymers such as polyethylenethioxythiophene (PEDOT), P3HT, P30T and MEH-PPV.

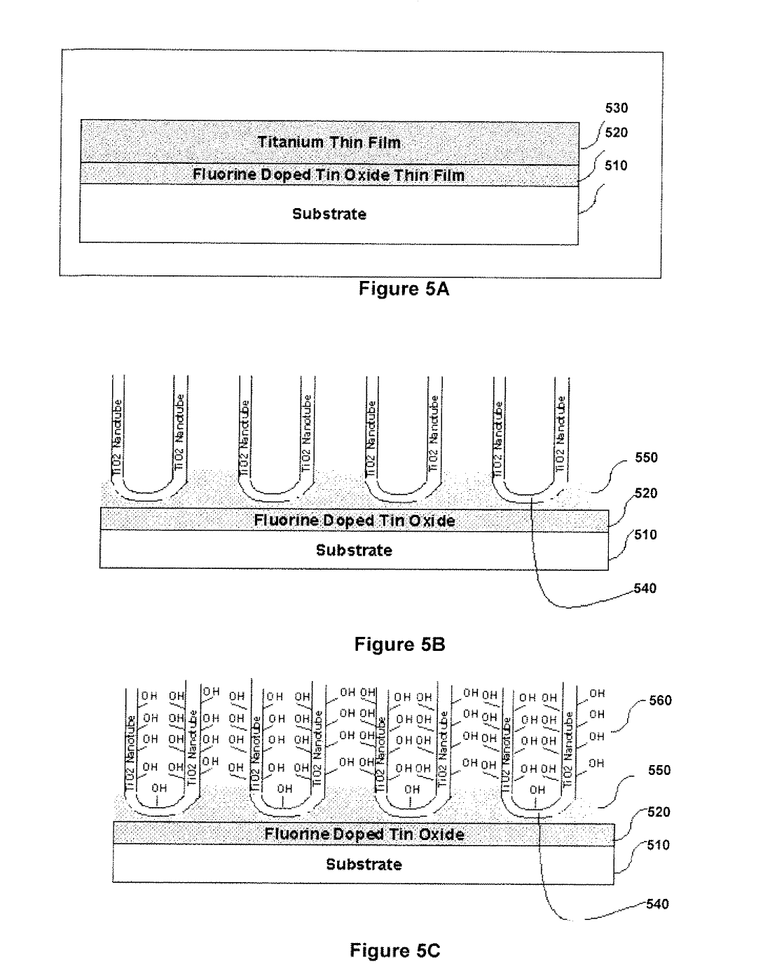

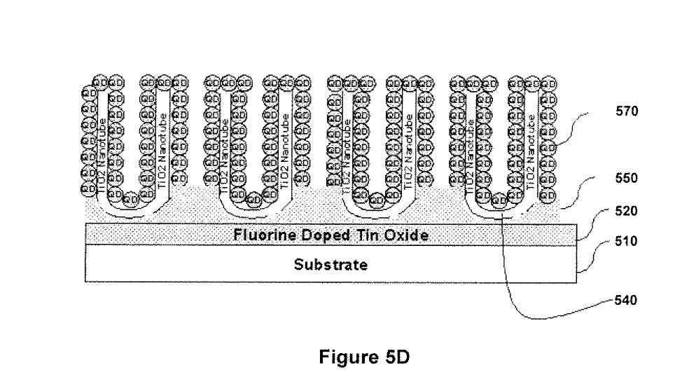

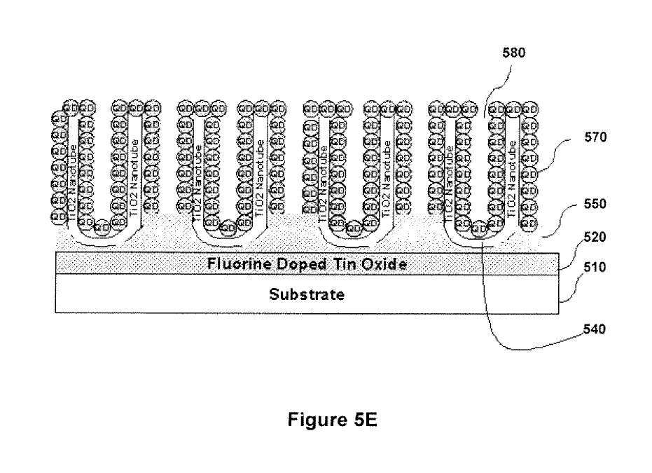

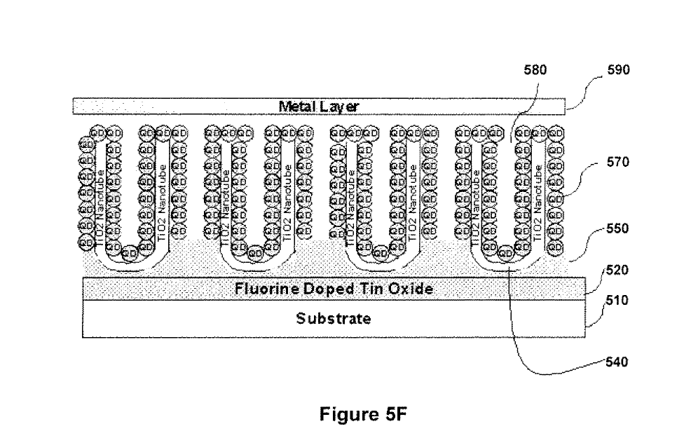

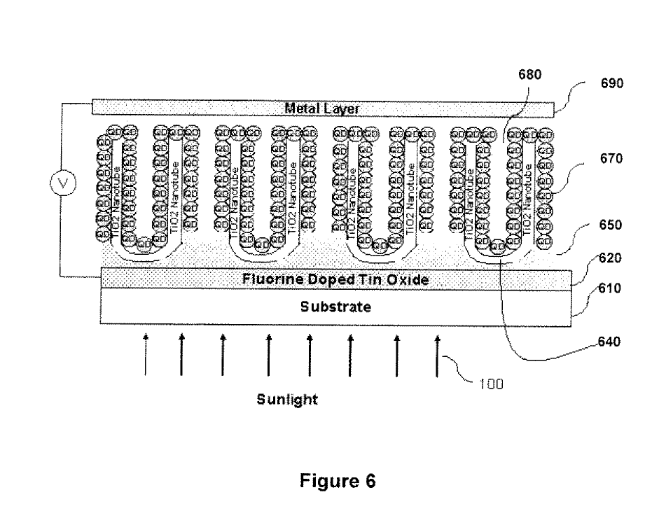

A solar cell incorporating the aforementioned nanostructures, nanoparticles, and hole transport layer and first and second electrodes, at least one of which is transparent to solar radiation, is shown in FIG. 6. This solar cell is made according to the protocol of Example 1 and as set forth in FIGS. 5A-5E.

It should be understood that the first layer containing the electron-conducting nanostructures is preferably not a continuous layer. Rather, in some cases the layer is made of nanostructures that are spaced. This allows introduction of the photosensitive nanoparticles between the nanostructures. In this embodiment, the distance between the nanostructures takes into account the size of the nanoparticles as well as the number of layers of nanoparticles to be applied to the nanostructure.

Given the disposition of the nanoparticles on the nanostructure, the photoactive layer need not be a uniform layer since it can conform to all or part of the three-dimensional structures of the nanostructured layer and may be either continuous or discontinuous.

Likewise, the hole transport layer has a structure that conforms to the shape of the underlying solar cell layers as well as the surface of the electrode with which it is in electrical contact. The hole transport layer in some embodiments is in contact with the photosensitive nanoparticles and the second electrode.

In preferred embodiments a blocking layer is provided between the whole conducting layer and the first electrode. This layer can be made concurrently during nanostructure formation, for example, when TiO₂ nanotubes are made on a titanium foil.

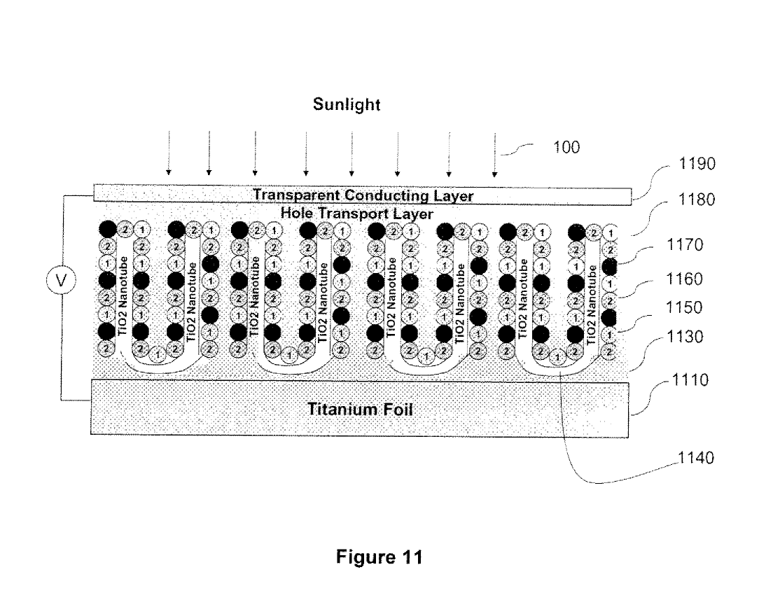

In some embodiments, the solar cell is a broadband solar cell that is capable of absorbing solar radiation at different wave lengths. Photosensitive nanoparticles generate electron-hole pairs when exposed to light of a specific wave length. The band gap of the photosensitive nanoparticles can be adjusted by varying the particle size or the composition of the nanoparticles. By combining a range of nanoparticle sizes and a range of the nanomaterials used to make the nanoparticles, broadband absorption over portions of or the entire solar spectrum can be achieved. Thus, in one embodiment, a mixture of photosensitive nanoparticles having a different size and/or composition can be layered on to the nanostructure of the first layer to make a broadband solar device such as that set forth in FIGS. 11-13.

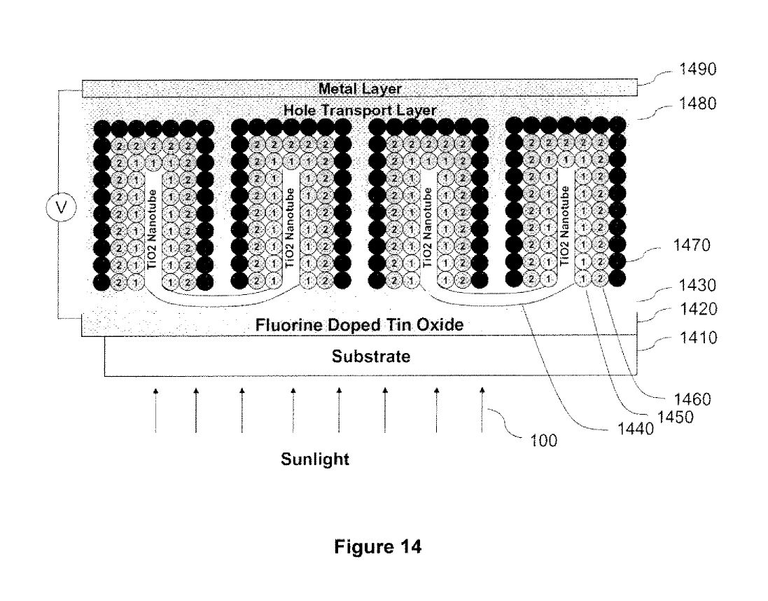

Alternatively, nanoparticles of a different size and/or composition can separately form a multiplicity of layers where each layer is responsive to a different portion of the solar spectrum. Examples of such solar cells can be found in FIGS. 14-17. In such embodiments, it is preferred that the nanoparticles be layered such that the layer closest to the nanostructure absorbs longer wavelength radiation than the material forming the second layer. If a third layer is present, it is preferred that the second layer absorb at a longer wavelength than that of the third layer etc.

### EXAMPLE 1

A nanoparticle sensitized solar cell is shown in FIG. 6. The key steps necessary to build the solar cell shown in FIG. 6 are depicted in FIGS. 5A-5F. By following methods known in the art a suitable transparent substrate (510) is first coated with fluorine doped Tin Oxide layer (520) followed by the deposition of a 300 nm-2 microns thick titanium thin film layer (530) by magnetron sputtering or other thin film deposition processes. By following methods known in the art Ti film (530) is anodized and heat treated to obtain transparent TiO₂ nanotubes (540). Anodizing conditions are optimized to obtain a barrier layer (550) which will act like an insulator and prevent cathode/anode shorts in the solar cells. The TiO₂ nanotube surfaces contain hydroxyl (—OH) functional groups (560). Nanoparticles made from luminescent materials such as CdSe, ZnSe, PbSe, InP, PbS, II-V materials with appropriate functional groups (—COOH, —NH2, —PO4 or SO3H) are reacted with the TiO₂ nanotubes to obtain nanoparticle (570) sensitized TiO₂ nanotubes. As shown in FIG. 5D, the nanoparticles decorate the nanotubes by forming a monolayer via a molecular self assembly process. A solvent wash is used to remove loosely bound nanoparticles. Since the nanoparticle deposition on TiO₂ nanotubes is controlled by the reaction of the —OH functional groups on TiO₂ with the nanoparticle functional groups (—COOH, —NH2, —PO4, —SO3), the nanoparticle thickness is automatically limited to a few mono-layers. A hole transporting layer (580) is then deposited. Hole transporting layer can be a polymeric material such as a conducting polymer (ex, PEDOT). Finally an electrode (transparent or translucent) (590) is deposited to complete the cell. If a translucent electrode (590) is deposited then the cell is oriented such that sunlight (100) falls on the transparent substrate (510) in FIG. 6. When sunlight falls on the solar cell shown in FIG. 6, electron hole pairs are generated by the nanoparticles. These nanoparticles can have various sizes, geometries and composition to cover the entire solar spectrum. Since the luminescent nanoparticles are attached directly to the electron conducting TiO₂ nanotubes, facile charge separation occurs thus minimizing any charge recombination. The Solar cell shown in FIG. 6 is expected to have a high efficiency and can be produced at a low cost relative to other thin film and silicon based technologies.

### EXAMPLE 2

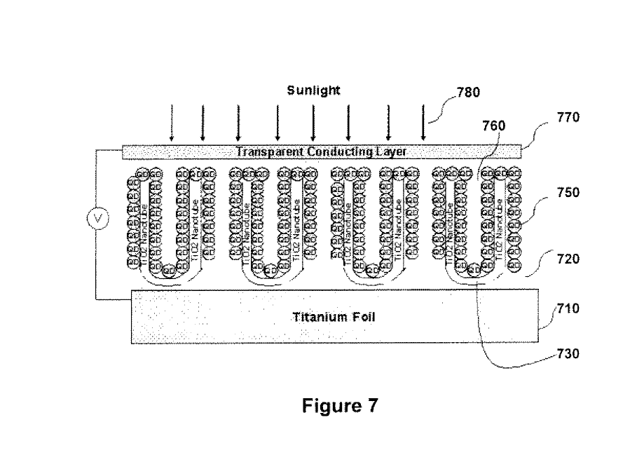

Another embodiment of nanoparticle sensitized solar cell is shown in FIG. 7. Key steps necessary to build the solar cell are similar to that shown in FIG. 5A-5F, except as follows. By following methods known in the art titanium metal foil (710) is anodized to obtain transparent TiO₂ nanotubes (730). Anodizing conditions are optimized to obtain a barrier layer (720) which will act like an insulator and prevent cathode/anode shorts in the solar cells. The TiO₂ nanotubes (730) surface contains hydroxyl (—OH) functional groups. Nanoparticles made from luminescent materials such as CdSe, ZnSe, PbSe, InP, PbS, III-V materials with appropriate functional groups (—COOH, —NH₂, —H₂PO₄ or —SO₃H) are reacted with the TiO₂ nanotubes to obtain nanoparticle (750) sensitized TiO₂ nanotubes. A hole transporting layer (760) is then deposited. The hole transporting layer can be a polymeric material such as a conducting polymer such as PEDOT. Finally a transparent conducting oxide layer (770) is deposited to complete the cell. The solar cell is oriented such that sunlight (780) falls on the transparent conducting oxide layer (770). The solar cell shown in FIG. 7 is expected to have high efficiency and can be produced at a low cost relative to other thin film and silicon based technologies.

### EXAMPLE 3

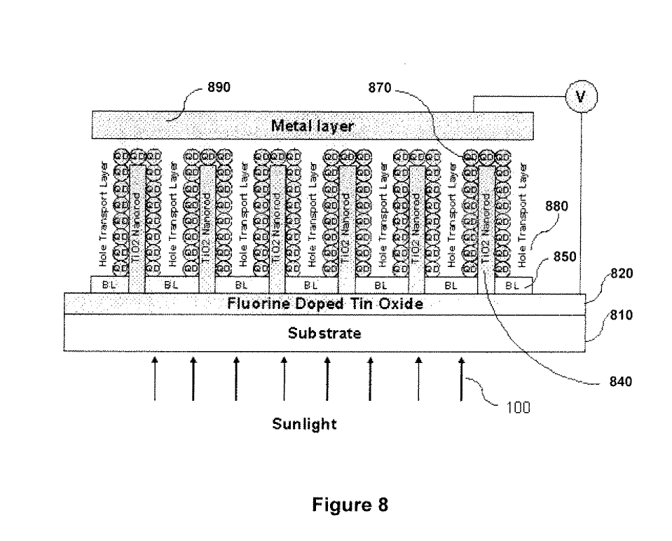

Another embodiment of a nanoparticle sensitized solar cell is shown in FIG. 8. By following methods known in the art a suitable transparent substrate (810) is first coated with fluorine doped tin oxide layer (820) followed by the deposition of a 300 nm 2 micron thick titanium thin film layer by magnetron sputtering or other thin film deposition processes. By following methods known in the art Ti film is anodized and heat treated to obtain transparent TiO₂ nanorods (840). Anodizing conditions are optimized to obtain a barrier layer (850) which will act like an insulator and prevent cathode/anode shorts in the solar cells. TiO₂ nanorod surfaces contain hydroxyl (OH) functional groups. Nanoparticles made from luminescent materials such as CdSe, ZnSe, PbSe, InP, PbS, III-V materials with appropriate functional groups (—COOH, —NH2, —PO4 or —SO3H) are reacted with the TiO₂ nanorods to obtain nanoparticle (870) sensitized TiO₂ nanorods. Nanoparticles decorate the nanorods by forming a monolayer via molecular self assembly process. A solvent wash is used to remove loosely bound nanoparticles. Since the nanoparticle deposition on TiO₂ nanorods is controlled by the reaction of the —OH functional groups on TiO₂ with the nanoparticle functional groups (—COOH, —NH2, —PO4, —SO3H), the nanoparticle thickness is automatically limited to that of a few mono-layers. Hole transporting layer (880) is then deposited. Hole transporting layer can be a polymeric material such as a conducting polymer, such as PEDOT. Finally an electrode (transparent or translucent) (890) is deposited to complete the cell. If a translucent electrode (890) is deposited then the cell is oriented such that sunlight (100) falls on the transparent substrate (810). When sunlight falls on the solar cell shown in FIG. 8, electron hole pairs are generated by the nanoparticles. Since the nanoparticles are attached directly to the electron conducting TiO₂ nanorods facile charge separation occurs thereby minimizing charge recombination.

### EXAMPLE 4

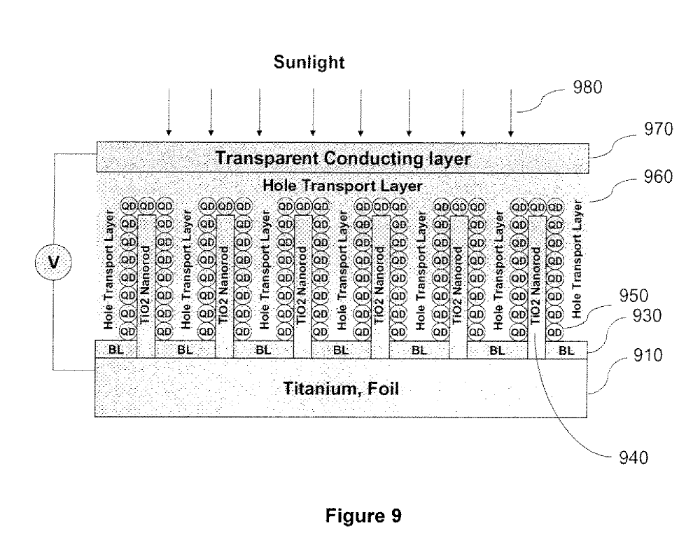

Another embodiment of nanoparticle sensitized solar cell is shown in FIG. 9. By following methods known in the art Titanium metal foil (910) is anodized to obtain transparent TiO₂ nanorods (930). Anodizing conditions are optimized to obtain a barrier layer (920) which will act like an insulator and prevent cathode/anode shorts in the solar cells. TiO₂ nanorods (930) surface contains hydroxyl (OH) functional groups. Nanoparticles made from luminescent materials such as CdSe, ZnSe, PbSe, InP, PbS, III-V materials with appropriate functional groups (—COOH, —NH2, —PO4 or —SO3H) are reacted with the TiO₂ nanorods to obtain nanoparticle (950) sensitized TiO₂ nanorods. The nanoparticles decorate the nanotubes by forming a monolayer via molecular self assembly process. A solvent wash is used to remove loosely bound nanoparticles. Since the nanoparticle deposition on TiO₂ nanorods is controlled by the reaction of the —OH functional groups on TiO₂ with the nanoparticle functional groups (—COOH, —NH2, —PO4, —SO3H), the nanoparticle thickness is automatically limited to that of a few mono-layers. Hole transporting layer (960) is then deposited. Hole transporting layer can be a polymeric material such as a conducting polymer, such as PEDOT. Finally a transparent conducting layer (970) such as ITO is deposited to complete the cell. The solar cell is oriented such that sunlight (980) falls on the transparent conducting layer (970). When sunlight falls on the solar cell shown in FIG. 9, electron hole pairs are generated by the luminescent nanoparticles. Since the nanoparticles are attached directly to the electron conducting TiO₂ nanorods facile charge separation occurs thus minimizing charge recombination.

### EXAMPLE 5

In an alternate embodiment of the solar cell of FIG. 6, the methods of Example 1 are followed except as follows. After TiO₂ nanotubes are formed, nanoparticles made from Si, Ge or SiGe with appropriate functional groups are reacted with the TiO2 nanotubes to obtain nanoparticle (570) sensitized TiO2 nanotubes. As shown in FIG. 6, the Si, Ge or SiGe nanoparticle (570) decorate the nanotubes by forming monolayers via molecular self assembly process.

A hole transporting layer (580) is then deposited. The hole transport layer can be p-doped Si or Ge. When Si nanoparticles are used it is desirable to use p-doped Si. This silicon layer can be amorphous silicon or multicrystalline silicon. The hole transport layer can be deposited by following methods known in the art for preparing thin films of Si or Ge. It is desirable to achieve conformal coating of the nanoparticles with this hole transport layer. This can be achieved by depositing Si or Ge thin films by atomic layer deposition process or chemical vapor deposition process Si and Ge thin film can be deposited on top of each other to increase light absorption. In such a case the Si and Ge films not only act as hole transporting layers but also act as light absorbing layers. The hole transporting layer can also be an organic semiconductor or a conducting polymeric material.

Another version of this embodiments a modification of the structure in FIGS. 6, 7, 8 and 9 to utilize Si, Ge or SiGe nanoparticles and/or p-doped Si and/or Ge for the hold conducting layer.

### EXAMPLE 6

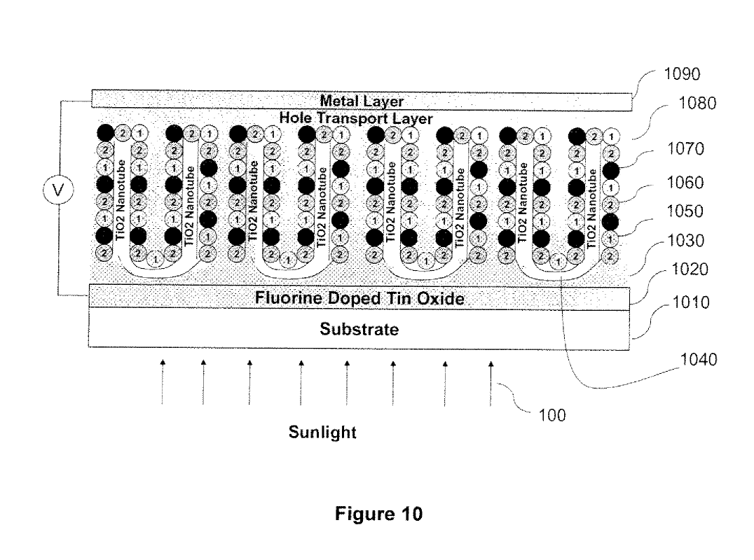

An embodiment of a broadband solar cell with multiple sizes of silicon nanoparticles attached to TiO₂ nanotubes built on fluorine doped tin oxide in shown in FIG. 10. By following methods known in the art a suitable transparent substrate (1010) if the protocol of Exhibit 1 is followed. However, nanoparticles of various sizes made from Si (1050), Ge (1060) or SiGe (1070) with appropriate functional groups are reacted with the TiO2 nanotubes (1040) to obtain a broadband mixture of nanoparticle sensitized TiO2 nanotubes. As shown in FIG. 10, the nanoparticles (1050, 1060 and 1070) of various sizes and/or composition decorate the nanotubes by forming mono-layers via molecular self assembly process.

A hole transporting layer (80) is then deposited. Hole transport layer can be p-doped Si or Ge. When Si nanoparticles are used it is desirable to use p-doped Si. This silicon layer can be amorphous silicon or multicrystalline silicon. The hole transport layer can be deposited by following methods known in the art for preparing thin films of Si or Ge. Si and Ge thin films can be deposited on top of each other to increase light absorption. In such a case the Si and Ge films not only act as hole transporting layers but also act as light absorbing layers. The hole transporting layer can also be an organic semiconductor or a conducting polymeric material.

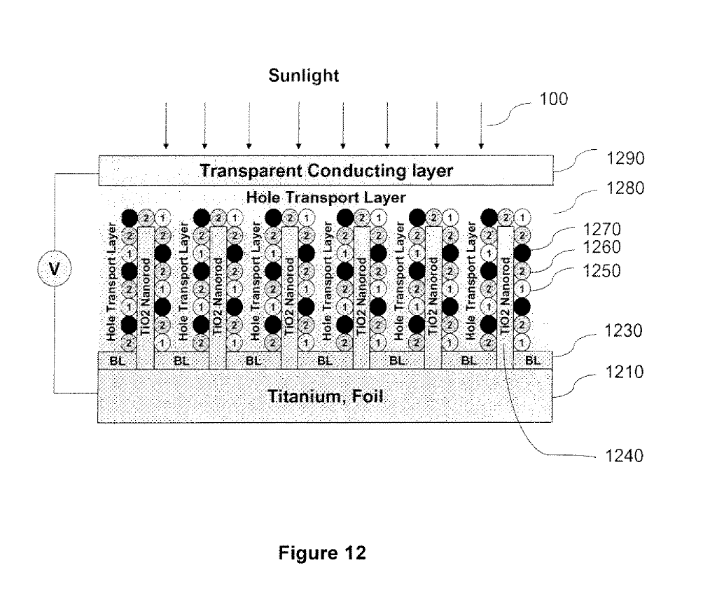

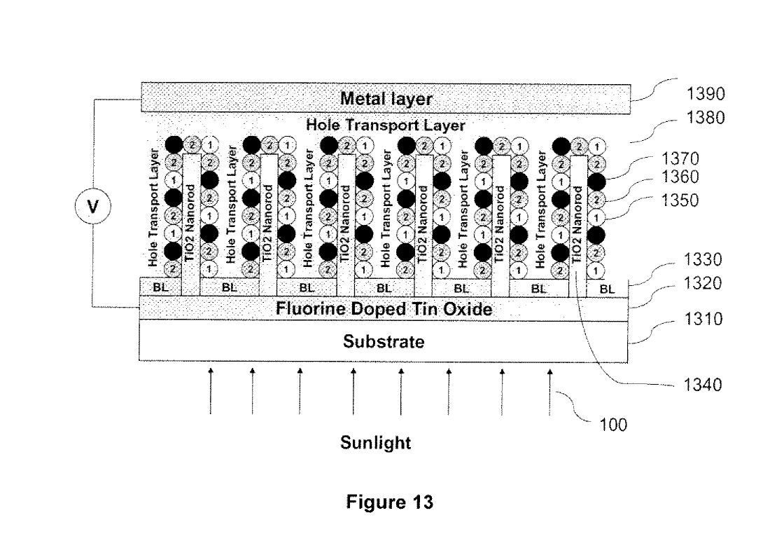

Another version of this embodiment is shown in FIG. 11. In this case a transparent conducting oxide (TCO) layer (1190) is deposited on top of hole transport layer (1180) and the solar cell is oriented such that sunlight falls on TCO. Another version of this embodiment with TiO2 nanorods (or nanowires) on flourine doped tin oxide is shown in FIG. 12. Another version of this embodiment with TiO2 nanorods (or nanowires) built on Titanium foil is shown in FIG. 13. Nanorods can be grown by methods known in the art include colloidal growth, chemical vapor deposition and MBE.

### EXAMPLE 7

An embodiment of a solar cell device with different sizes of silicon nanoparticles layered on TiO2 nanotubes built on fluorine doped tin oxide is shown in FIG. 14. The protocol of Example 1 was followed except as follows. After formation of the TiO₂ nanotubes (1440) nanoparticles made from Si, Ge or SiGe with appropriate functional groups are deposited on TiO2 nanotubes using molecular self assembly processes to obtain multi-layer nanoparticle (1450, 1460 and 1470) sensitized TiO2 nanotubes. As shown in FIG. 14, the nanoparticles (1450, 1460 and 1470) decorate the nanotubes by forming multiple layers of nanoparticles. Each of these layers is deposited separately by using a molecular self assembly process. Each layer can contain a narrow range of sizes of nanoparticles made from Si or Ge. Each layer can be designed to absorb a narrow range of solar spectrum. Multiple layers (1450, 1460, 1470) are stacked in such a way to cover the desired part of (or all of) the solar spectrum. The number of layers can range from 2-10. A minimum number of layers is desirable to reduce manufacturing cost. By adjusting the particle size range used in each layer a solar cell with a preferred number of layers can be designed. An example shown in FIG. 14 has three layers with layer 1 (450) absorbing in IR range, layer 2 (1460) absorbing in visible range and layer 3 (1470) absorbing in near UV range. Nanoparticles of Si and Ge of various sizes can be combined in this embodiment.

A hole transporting layer (80) is then deposited. The hole transport layer can be p-doped Si or Ge. When Si nanoparticles are used it is desirable to use p-doped Si. This silicon layer can be amorphous silicon or multicrystalline silicon. The hole transport layer can be deposited by following methods known in the art for preparing thin films of Si or Ge. Hole transporting layers can also be an organic semiconductor or a conducting polymeric material.

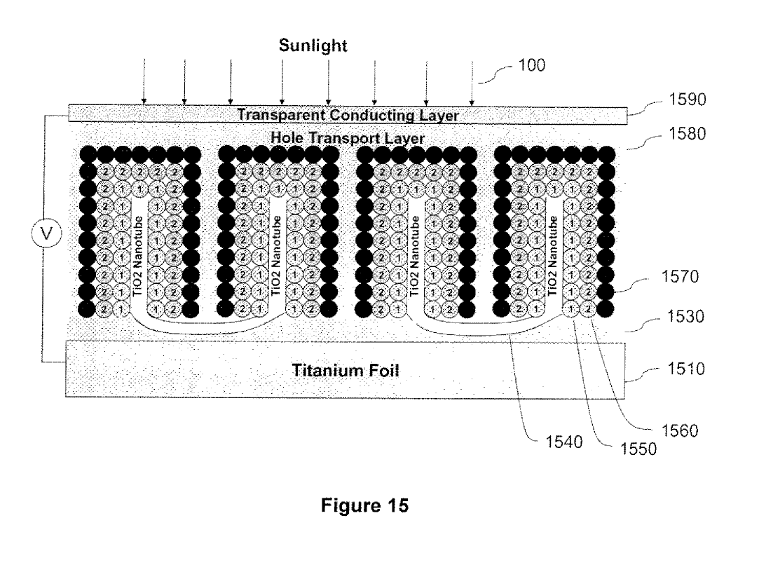

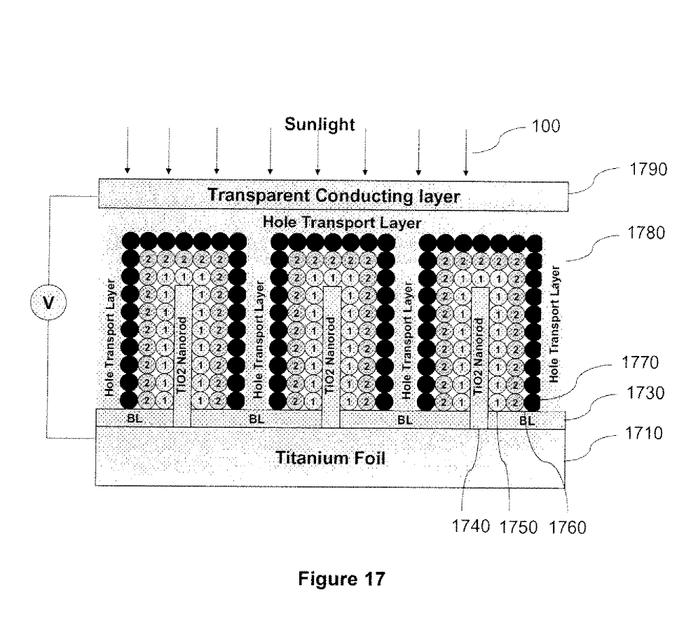

Other versions of this embodiment are shown in FIGS. 15, 16 and 17. In FIGS. 15 and 17, a transparent conducting oxide (TCO) layer (1590 or 1790) is deposited on top of hole transport layer (1580 or 1780) and the solar cell is oriented such that sunlight falls on the TCO.

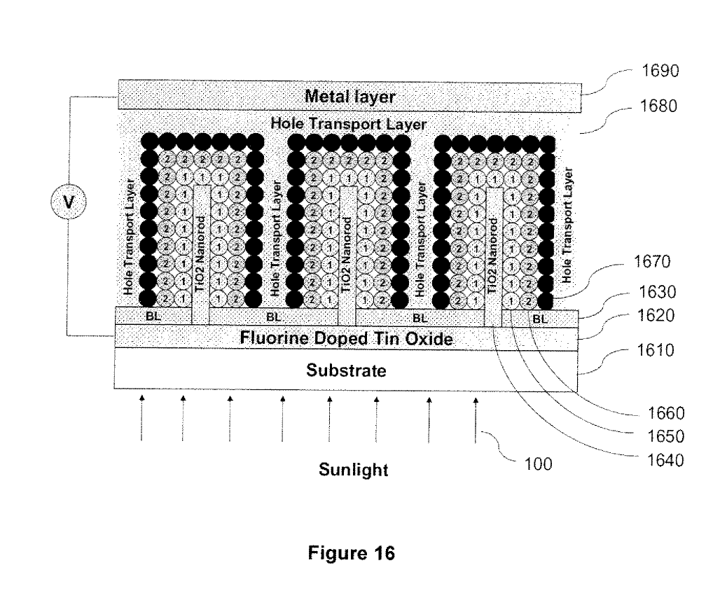

Another version of this embodiment with TiO2 nanorods (or nanowires) on flouring doped tin oxide is shown in FIG. 16.

Another version of this embodiment with TiO2 nanorods (or nanowires) built on Titanium foil is shown in FIG. 15. Nanorods can be grown by methods known in the art include colloidal growth, chemical vapor deposition and MBE.

### EXAMPLE 8

In another embodiment the protocol of Example 1 is modified as follows. After TiO₂ nanotube formation, photosensitive nanoparticles made from Group II-V, II-VI, II-IV with appropriate functional groups are reacted with the TiO₂ nanotubes to obtain nanoparticle (590) sensitized TiO2 nanotubes. (See FIG. 6.) Examples of these nanoparticles include CdSe, CDTe. ZnSe, PbSe, ZnS, PbS. As shown in FIG. 6, the nanoparticles decorate the nanotubes by forming monolayers via molecular self assembly process.

A hole transporting layer (580) is then deposited. The hole transport layer can be p-doped semiconductor layer such as Si or Ge. The Si or Ge layer can be amorphous or multicrystalline. Hole transport layer can also be a metal oxide layer such as aluminum oxide, nickel oxide, etc. The hole transport layer can be deposited by following methods known in the art for preparing thin films of these materials. For example, Si or Ge thin films can be deposited by atomic layer deposition or chemical vapor depositions Si and Ge thin film can be deposited on top of each other to increase light absorption. In this case, Si and (Ge films not only act as hole transporting layers but also act as light absorbing layers. The thickness of the hole transporting layer can be adjusted to minimize resistance to hole conduction through this layer while maximizing light absorption. Hole transporting layer can also be an organic semiconductor or a conducting polymeric material.

Another version of this embodiment with TiO₂ nanotubes built on titanium foil is shown in FIG. 7. In this case a transparent conducting oxide (TCO) layer (770) is deposited on top of hole transport layer (760) and the solar cell is oriented such that sunlight falls on the TCO. Another version of this embodiment with TiO₂ nanorods (or nanowires) on fluorine doped tin oxide is shown in FIG. 8. Another version of this embodiment with TiO₂ nanorods (or nanowires) built on titanium foil is shown in FIG. 9. Nanorods can be grown by methods known in the art which include colloidal growth, chemical vapor deposition and molecular beam epitaxy (MBE).

### EXAMPLE 9

In another embodiment the protocol of Example 8 is modified as follows. Instead of Si or Ge hole transporting layers the hole transporting layer is made from a p-doped semiconductor layer such as Si or Ge.

Other versions of this embodiment are shown in FIGS. 11, 12 and 13.

### EXAMPLE 10

In another embodiment, the broadband solar cell described in Example 6 is modified as follows. After TiO₂ nanotube (1440) formation (see FIG. 14), photosensitive nanoparticles of various sizes made from Group II-V, II-VI, II-IV, etc. with appropriate functional groups are reacted with the TiO2 nanotubes (1450, 1460 and 1470) to obtain broadband mixture of nanoparticle (1450, 1460 and 1470) sensitized TiO2 nanotubes. Examples of the photosensitive nanoparticles include CdSe, ZnSe, PhSe, CdTe, PbS, etc. Nanoparticle size can vary from 2-50 nm, preferably from 2-10 nm. The photosensitive nanoparticles with appropriate functional groups are deposited on TiO2 nanotubes using molecular self assembly processes to obtain multi-layer nanoparticle sensitized TiO₂ nanotubes. Each of these layers can be deposited separately by using molecular self assembly process. Each layer can contain a narrow range of sizes of photosensitive nanoparticles and can be designed to absorb a narrow range of solar spectrum. Multiple layers (1450, 1460 and 1470) are stacked in such a way to cover the desired part of (or all of) the solar spectrum. The number of layers can range from 2-10. The minimum number of layers is desirable to reduce manufacturing cost. By adjusting the particle size range used in each layer a solar cell with the preferred number of layers can be designed. In FIG. 14 layer 1 (1450) absorbs in IR range, layer 2 (1460) absorbs in visible range and layer 3 (1470) absorbs in near UV range. Nanoparticles of PbSe. CdSe and ZnSe of various sizes can be combined to build this multilayer structure shown in FIG. 14.

A hole transporting layer (1480) is then deposited. The hole transport layer can be p-doped semiconductor layer such as Si or Ge. This layer can be amorphous or multicrystalline. Si and Ge thin film can be deposited on top of each other to increase light absorption. Si and Ge films not only act as hole transporting layers but also act as light absorbing layers. The thickness of hole transporting layer can be adjusted to minimize resistance to hole conduction through this layer while maximizing light absorption. Hole transporting layer can also be an organic semiconductor or a conducting polymeric material.

Other versions of this embodiment are shown in FIGS. 15, 16 and 7.

What is claimed is:

1. A photovoltaic devise comprising
first and second electrodes at least one of which is transparent to solar radiation;
a first layer comprising an electron conducting nanostructure in electrical communication with said first electrode;
a photoactive layer comprising photosensitive nanoparticles in proximity to said electron conducting nanostructure; and
a hole conducting layer in contact with said photoactive layer and said second electrode.

2. The photovoltaic devise of claim 1 further comprising a blocking layer between said hole conducting layer and said first electrode.

3. The photovoltaic devise of claim 1 wherein said electron conducting nanostructure comprises a nanotube, nanorod, or nanowire.

4. The photovoltaic devise of claim 3 wherein said nanostructure comprises a nanotube.

5. The photovoltaic devise of claim 4 wherein said nanotube comprises titanium dioxide.

6. The photovoltaic devise of claim 1 wherein said photosensitive nanoparticle comprises a quantum dot, a nanorod, a nanobipod, a nanotripod, a nanomultipod or nanowire.

7. The photovoltaic devise of claim 6 wherein said photosensitive nanoparticle is a quantum dot.

8. The photovoltaic devise of claim 1 wherein said photosensitive nanoparticle is covalently attached to said nanostructure.

9. The photovoltaic devise of claim 1 wherein said photosensitive nanoparticle comprises CdSe, ZnSe, PbSe, InP, PbS, ZnS, Si, Ge, SiGe, CdTe, CdHgTe, or Group II-VI, II-IV or III-V materials.

10. The photovoltaic devise of claim 1 wherein said photoactive layer comprises first and second nanoparticles that adsorb radiation from different portions of the solar spectrum.

11. The photovoltaic devise of claim 10 wherein said first and second nanoparticles differ in compositions.

12. The photovoltaic devise of claim 10 wherein said first and second nanoparticles have different size.

13. The photovoltaic devise of claim 10 wherein said first and said second nanoparticles differ in size and composition.

14. The photovoltaic devise of claim 1 further comprising a second photoactive layer where said first and said second layers adsorb radiation from different portions of the solar spectrum.

15. The photovoltaic devise of claim 14 wherein the nanoparticles of said first and said second photoactive layers differ in composition.

16. The photovoltaic devise of claim 14 wherein the nanoparticles of said first and said second photoactive layers have different sizes.

17. The photovoltaic device of claim 14 wherein the nanoparticles of said first and said second photosensitive layers differ in size and composition.

18. The photovoltaic devise of claim 1 wherein said hole conducting layer comprise a hole conducting polymer.

19. The photovoltaic devise of claim 18 where said hole conducting polymer comprises a p-type semiconducting polymer.

20. The photovoltaic devise of claim 19 where said p-type semiconducting polymer comprises P3HT, P3OT, MEH-PPV or PEDOT.

21. The photovoltaic devise of claim 20 wherein said polymer comprises PEDOT.

22. The photovoltaic devise of claim 1 wherein said hole conducting layer comprises a p-type semiconductor.

23. The photovoltaic devise of claim 22 wherein said p-type semiconductor is p-doped Si, p-doped Ge or p-doped SiGe.

24. The photovoltaic devise of claim 22 wherein said p-type semiconductor comprises p-doped amorphous silicon, p-doped microcrystalline silicon or p-doped nanocrystalline silicon.

25. The photovoltaic devise of claim 1 wherein said hole conducting layer comprises two or more layers of p-type semiconductor.

26. The photovoltaic devise of claim 25 wherein said p-type semiconductor layers comprise a p-doped silicon layer, a p-doped germanium layer or a p-doped SiGe layer.

27. A method for making a photovoltaic devise comprising:
forming a first layer comprising an electron conducting nanostructure on a first electrode where said first layer is in electrical communication with said first electrode;
forming a photoactive layer comprising photosensitive nanoparticles on said electron conducting nanostructure; and
forming a hole transport layer on said photoactive layer; and
forming a said second electrode on said hole transport layer;
wherein at least one of said first and second electrodes is transparent to solar radiation.

28. The method of claim 27 further comprising forming a blocking layer before said forming said nanostructure or said forming of said hole conducting layer.

29. The method of claim 27 wherein said forming of said photoactive layer comprises the use of different nanoparticles to make a photoactive layer comprising a random distribution of said different nanoparticles.

30. The method of claim 27 wherein said photoactive layer comprises at least two layers of different nanoparticles and said method of forming said photoactive layer comprises forming a layer of first nanoparticles on said nanostructure and forming a layer of second nanoparticles on the layer of said first nanoparticles, where said first and second nanoparticles are different.
